(19) United States
(12) Patent Application Publication
(10) Pub. No.: US 2008/0290413 A1
(43) Pub. Date: Nov. 27, 2008

(54) SOI MOSFET WITH A METAL SEMICONDUCTOR ALLOY GATE-TO-BODY BRIDGE

(75) Inventors: Jack A. Mandelman, Flat Rock, NC (US); Haining S. Yang, Wappingers Falls, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/751,222

(22) Filed: May 21, 2007

(51) Int. Cl. H01L 27/12

(52) U.S. Cl. 257/347; 257/E27.111

(57) ABSTRACT

A body contact region is formed in a portion of the active region. A gate dielectric and a gate conductor layer are formed on the active region and patterned to define a gate electrode. A portion of the gate electrode is removed to expose a top surface of the body contact region adjoining a sidewall of the gate dielectric which adjoins a sidewall of the gate conductor. A substrate metal semiconductor alloy is formed on the top surface of the body contact region, and a gate metal semiconductor alloy is formed on the sidewall of the gate conductor. The substrate metal semiconductor alloy and the gate metal semiconductor alloy are adjoined during formation, providing a gate-to-body bridge of a MOSFET formed on the active region.

### FIELD OF THE INVENTION

The present invention relates to semiconductor devices, and particularly to semiconductor-on-insulator (SOI) field effect transistors with a metal semiconductor alloy gate-to-body bridge and methods of manufacturing the same.

### BACKGROUND OF THE INVENTION

With continuous scaling of dimensions in each successive generation of complementary metal oxide semiconductor (CMOS) technology, simultaneously providing a low off-current and a high on-current in metal oxide semiconductor field effect transistors (MOSFETs) has become increasingly challenging. On one hand, as supply voltages are decreased to reduce active power consumption, threshold voltages of MOSFETs need to be decreased to provide high performance of CMOS devices. On the other hand, static sub-threshold voltage slope of current as a function of gate voltage may not be reduced below 60 mV/decade at 25° C., and consequently, static power dissipation due to a high off-current increases with reduction of the threshold voltage of the MOSFETs.

In most CMOS circuits, switching events of the MOSFETs occur for a relatively small fraction of the total time during a circuit operation, and consequently, management of off-current is critical in reducing total power consumption of the circuit. With the combination of high off-current, high on-current, and ever increasing circuit density, the areal power dissipation density in 65 nm node semiconductor technology is expected to approach 100 W/cm².

Furthermore, semiconductor-on-insulator (SOI) devices display floating body effects in which the switching behavior is dependent on the history of the devices. Consequently, floating body effects contribute to poor gate control and/or parasitic conduction effects. For example, SOI CMOS logic circuits may display variable switching delay times caused by a floating body, and consequently, present severe design challenges for timing dependent circuits. Another example is a pass gate device in a static random access memory (SRAM) cell which may parasitically conduct when a source diffusion is pulled to a low voltage even when the gate voltage is low. SRAM cells may also be adversely affected by a time dependent threshold voltage mismatch between adjacent pull-up transistors and pull-down transistors that is caused by the floating body effect, in which the threshold voltage mismatch degrades signal margin and cell stability. A similar effect is also manifested in a dynamic random access memory (DRAM) transfer device, which may have excessive leakage current due to dynamic threshold voltage lowering induced by the floating body while an adjacent DRAM cell is accessed through the same bit line.

To alleviate the above discussed power versus performance device scalability dilemma facing the CMOS technology below 65 nm node and the SOI floating body effects that are detrimental to CMOS device performance, CMOS devices that concurrently provide high performance and low power dissipation density and mitigate the SOI floating body effects have been investigated.

SOI MOSFETs operating with a gate electrically connected to the body have been proposed as a means of providing a high on-current to off-current ratio at low operating voltages, e.g., an operating voltage below the band gap of a semiconductor, which is 0.70V in the case of silicon. In the off state, the body is tied to ground through the gate, preventing body charging and threshold voltage lowering. When the MOSFET is turned on, the body voltage is elevated to the transistor operating voltage, Vdd, which drastically lowers the threshold voltage and provides a superior overdrive in current in comparison with a comparable transistor with a grounded body or a floating body.

Thus, the SOI MOSFET with the gate tied to the body can be viewed as a MOSFET having dynamic back-bias control. When a low off-current is needed, the back-bias voltage is zero, i.e., the body is grounded. When a high on-current is needed, the back-bias voltage is elevated to the transistor operating voltage, Vdd. In this mode of operation, the transistor operating voltage is lower than the band gap of the semiconductor material comprising the body and the source. The body to source junction is not strongly biased in the on-state since the voltage across the body and the source is less than the band gap of the semiconductor material comprising the body and the source. Due to the high on-current to off-current ratio, an SOI MOSFET with the gate tied to the body becomes increasingly attractive as the transistor operating voltage, Vdd is reduced below 0.7V, which is the band gap of silicon.

Referring to FIG. 1, a graph showing a comparison of Ids-Vgs characteristics, i.e., the effect on the source-drain current Ids in response to the gate-to-source voltage Vgs, among three hypothetical devices having the same gate length and width is shown. The first device is an n-type MOSFET in which the body is grounded, i.e., held at 0.0V. The second device is an n-type MOSFET in which the body is held at a constant voltage of 0.6V. The third device is an n-type MOSFET in which the gate is tied to the body. Superior on-current to off-current ratio of the third device is apparent in this graph.

The prior arts provides structures that provide connection between the gate and the body of a MOSFET. U.S. Pat. No. 5,559,368 to Hu et al. provides an n-type MOSFET in which an aluminum contact plug fills a via hole which is formed through a widened portion of a gate conductor to a p-doped region abutting the body of the n-type MOSFET. The aluminum contact plug provides a bridge between the gate conductor and the body. Metal semiconductor alloys are not employed in the electrical connection between the gate conductor and the body, and aluminum, which is a back-end-of-line (BEOL) metal that poses metallic contamination risk if employed prior to completion of front-end-of line (FEOL) devices, needs to be formed through BEOL dielectric materials.

The '368 patent also provides a gate-to-body electrical connection formed by a gate conductor formed by two layers of polysilicon. A first polysilicon layer is formed on a gate dielectric, followed by formation of an opening in the first polysilicon layer and formation of a second polysilicon layer that contacts a p-doped region abutting the body. However, the polysilicon gate of an n-type MOSFET, which is typically doped with n-type dopants, forms a reversed biased PN junction with the body, rendering the body tie ineffective. Similar problem occurs for a p-type MOSFET since the polysilicon gate is p-doped and the body is n-doped. Two layers of polysilicon deposition are required and no metal semiconductor alloy is employed in the gate-to-body tie.

U.S. Pat. No. 5,821,769 to Douseki discloses a structure in which a body connection portion of an active area is masked from source and drain implantation, metal contacts are formed to a gate conductor and to the body connection portion respectively, and a metal wiring connects the metal contacts to electrically connect the gate conductor and the body connection portion. A BEOL wiring is employed in the structure connecting the gate conductor to the body connection portion.

U.S. Pat. No. 6,060,750 to Hisamoto et al. discloses a gate-to-body tie formed between a gate conductor and a sidewall of an silicon-on-insulator island. The gate-to-body tie is formed by etching through a lower gate layer and active areas of the silicon-on-insulator island and depositing and subsequently patterning an upper gate layer. The upper gate layer contacts the bare SOI sidewalls and a block mask is employed to prevent the dopants of source and drain implantation from entering the body contact area. The upper and lower gate layers comprise polysilicon, and no metal semiconductor alloy is employed in the gate-to-body tie.

While the prior art provides structures for SOI MOSFETs with a gate-to-body bridge and methods of manufacturing the same, further improvements are desired. Specifically, the gate-to-body bridge needs to avoid any reverse biased PN junction. A single gate polysilicon layer is preferred to multiple polysilicon layer for lower processing costs. A compact structure that requires less metal contacts and no BEOL wiring is preferred to structures having multiple metal contacts and/or requires a BEOL wiring.

In view of the above, there is a need to provide an SOI MOSFET structure having a gate-to-body bridge employing a simple structural connection and providing solid electrical connection between the gate and the body, and methods of manufacturing the same.

### SUMMARY OF THE INVENTION

The present invention addresses the needs described above by providing an SOI MOSFET structure having a metal semiconductor alloy gate-to-body bridge and methods of manufacturing the same.

In the present invention, an active region surrounded by shallow trench isolation is formed out of a top semiconductor layer of a semiconductor-on-insulator substrate. A body contact region, which may optionally be heavily doped with dopants, is formed in a portion of the active region by a masked implantation, A gate dielectric and a gate conductor layer are formed on the active region and patterned to define a gate electrode. A portion of the gate electrode is removed to expose a top surface of the body contact region adjoining a sidewall of the gate dielectric, which adjoins a sidewall of the gate conductor. A substrate metal semiconductor alloy is formed on the top surface of the body contact region, and a gate metal semiconductor alloy is formed on the sidewall of the gate conductor. The substrate metal semiconductor alloy and the gate metal semiconductor alloy are adjoined during formation, providing a gate-to-body bridge of a MOSFET formed on the active region.

According to an aspect of the present invention, a semiconductor-on-insulator (SOI) metal oxide semiconductor field effect transistor (MOSFET) comprises:
a. an active region surrounded by shallow trench isolation and containing a body, source and drain regions, and a body contact region, wherein the body contact region abuts the body;
b. a buried insulator layer abutting the active region and the shallow trench isolation;
c. a handle substrate abutting the buried insulator layer;
d. a gate stack abutting the body and containing a gate dielectric and a gate conductor;
e. a substrate metal semiconductor alloy region abutting the body contact region; and
f. a gate metal semiconductor alloy region abutting a gate conductor sidewall and abutting the substrate metal semiconductor alloy region.

In the instant invention, the body and the body contact region may be doped with dopants of a first conductivity type and the source and drain region may be doped with dopants of a second conductivity type, wherein the first conductivity type is the opposite of the second conductivity type. The body contact region may be heavily doped, and may have an atomic doping concentration from about 1.0×10²⁰/cm³ to about 3.0×10²¹/cm³. The gate conductor comprises a semiconductor material doped with dopants of the second conductivity type.

The inventive SOI MOSFET may further comprise a gate dielectric sidewall adjoining the gate conductor sidewall and the body contact region.

The inventive SOI MOSFET may further comprise a dielectric gate spacer abutting at least another gate conductor sidewall and not abutting the gate conductor sidewall, wherein the dielectric gate spacer is topologically homeomorphic to a closed 3-dimensional unit ball, D³, and is not topologically homeomorphic to a torus.

The gate conductor may be topologically homeomorphic to a torus, the gate metal semiconductor alloy region may be topologically homeomorphic to a torus, and the adjoined structure of the gate metal semiconductor alloy region and the gate metal semiconductor alloy may be topologically homeomorphic to a closed 3-dimensional unit ball, D³.

A substrate metal semiconductor alloy in the substrate metal semiconductor alloy region and a gate metal semiconductor alloy in the gate metal semiconductor alloy region may be derived from the same metal or metal alloy.

The substrate metal semiconductor alloy region and the gate metal semiconductor alloy may be the same metal silicide.

According to another aspect of the present invention, methods of forming the SOI MOSFET are also disclosed.

### BRIEF DESCRIPTION OF THE DRAWINGS

FIG. 1 is a graph comparing Ids-Vgs characteristics, i.e., the response of source-drain current Ids in response to gate-to-source voltage Vgs, among three hypothetical devices having the same gate length and width.

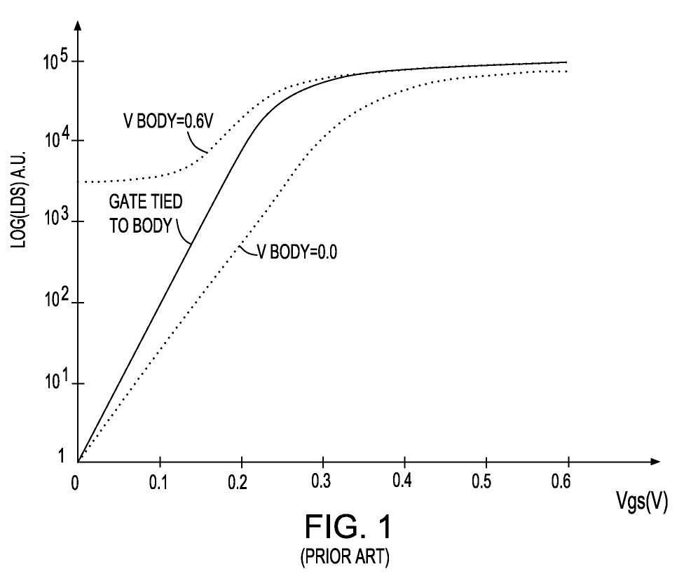

FIGS. 2A-3B show a first exemplary structure according to a first embodiment of the present invention. FIGS. 2A and 3A are top-down views of the first exemplary structure. FIGS. 2B and 3B are vertical cross-sectional views of the first exemplary structure along the plane B-B′ of FIG. 2A and of FIG. 3A, respectively.

FIGS. 4A-4B show a second exemplary structure according to a second embodiment of the present invention. FIG. 4A is a top-down view of the second exemplary structure. FIG. 4B is a vertical cross-sectional view of the second exemplary structure along the plane B-B′ of FIG. 4A.

### DETAILED DESCRIPTION OF THE INVENTION

As stated above, the present invention relates to semiconductor-on-insulator (SOI) field effect transistors with a metal semiconductor alloy gate-to-body bridge and methods of manufacturing the same, which are now described in detail with accompanying figures. It is noted that like and corresponding elements are referred to by like reference numerals.

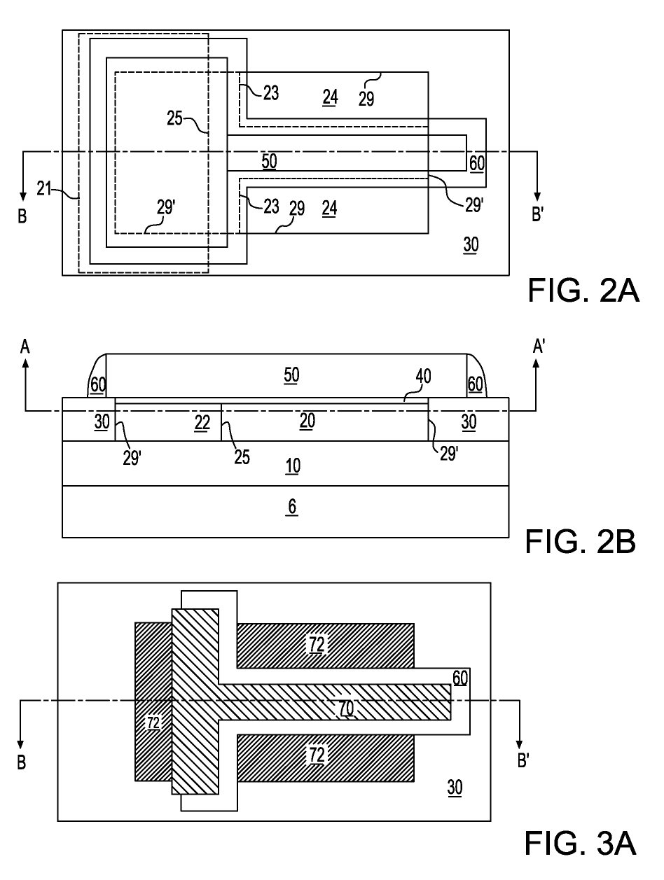

Referring to FIGS. 2A and 2B, a first exemplary structure according to a first embodiment of the present invention is shown. FIG. 2A is a top-down view of the first exemplary structure in which structural boundaries in the plane A-A′ in FIG. 2B are also shown in dotted lines. FIG. 2B is a vertical cross-sectional view of the first exemplary structure along the plane B-B′ in FIG. 2A.

The first exemplary structure of the present invention comprises a semiconductor-on-insulator (SOI) substrate containing a handle substrate 8, a buried insulator layer 10, and an active region comprising a semiconductor material and surrounded by shallow trench isolation 30. The active region comprises a body 20, source and drain regions 24, and a body contact region 22. The boundary between the active region, which has a rectangular cross-sectional area in the first exemplary semiconductor structure, comprises exposed active region boundaries 29 that are not covered by a stack of gate dielectric 40 and a gate conductor 50 and covered active region boundaries 29′ that are covered by the stack of gate dielectric 40 and the gate conductor 50. In general, non-rectangular active areas may be formed.

The body 20 is doped with dopants of a first conductivity type. The first conductivity type is p-type for an n-type SOI MOSFET structure, or alternatively, n-type for a p-type SOI MOSFET structure. The atomic doping concentration of the body 20 may be from about 1.0×10¹⁴/cm³ to about 3×10¹⁹/cm³. In FIG. 2A, the body 20 is a T-shaped region bounded by the set of dotted lines representing a body to body contact region boundary 25, body to source and drain region boundaries 23, and portions of the covered active region boundary 29′ that adjoin the body to body contact region boundary 25 or the body to source and drain region boundaries 23. The body 20 is formed by blocking the area of the body during various ion implantation processes that introduce dopants to the source and drain regions 24 and into the body contact region 22.

The source and drain regions 24 are doped with dopants of a second conductivity type. The second conductivity type is the opposite type of the first conductivity type, i.e., the second conductivity type is n-type for an n-type SOI MOSFET structure, or alternatively, p-type for a p-type SOI MOSFET structure. The atomic doping concentration of the source and drain regions 24 may be from about 1.0×10²⁰/cm³ to about 3×10²¹/cm³. The source and drain regions 24 are bounded by the exposed active region boundaries 29 and the body to source and drain region boundaries 23.

The body contact region 22 is doped with dopants of the first conductivity type. The body contact region 22 may have the same doping concentration as the body 20, or preferably, may be heavily doped at an atomic doping concentration from about 1.0×10²⁰/cm³ to about 3×10²¹/cm³. The body contact region 22 is bounded by the body to body contact region boundary 25 and the covered active region boundaries 29′.

The first exemplary structure further comprises a gate stack formed directly on the active region (20, 22, 24). The gate stack comprises a gate dielectric 40 and a gate conductor 50. The gate dielectric 40 may comprise a conventional dielectric material such as an oxide, a nitride, or a stack thereof. Alternately, the may comprise a high-K dielectric material such as HfO₂, ZrO₂, Al₂O₃, TiO₂, La₂O₃, SrTiO₃, LaAlO₃, Y₂O₃ and mixtures thereof. The physical thickness of the gate dielectric 40 may vary, but typically, the gate dielectric has a thickness from about 0.5 nm to about 10 nm, with a thickness from about 1 nm to about 3 nm being more typical.

The gate conductor 50 comprises a semiconductor material that is capable of forming an alloy with a metal. For example, the gate conductor 50 may comprise silicon that may form a metal silicide when reacted with a metal. The gate conductor 50 may comprise germanium that may form a metal germanide when reacted with a metal. The gate conductor 50 may comprise a compound semiconductor that can form a metal-compound semiconductor alloy. The gate conductor 50 may be undoped, doped with dopants of the first conductivity type, or doped with dopants of the second conductivity type. In case the gate conductor 50 comprises a silicon containing material such as polysilicon, it is preferable to doped the gate conductor 50 with dopants of the second conductivity type. Typically, a heavy doping with an atomic concentration from about 1.0×10²⁰/cm³ to about 3×10²¹/cm³ is preferred.

A dielectric gate spacer 60 typically abuts sidewalls of the gate conductor 50. The dielectric gate spacer 60 comprises a dielectric material such as silicon oxide, silicon nitride, or a stack thereof. Multiple layers of dielectric materials may be employed in the dielectric gate spacer.

The manufacture of the first exemplary structure in FIGS. 2A and 2B follows standard semiconductor manufacturing sequence except that an implant mask is preferably employed to define an implant area 21 containing the body contact region 22 and an ion implantation is preferably performed to heavily dope the body contact region 22 with dopants of the first conductivity type.

Specifically, a semiconductor-on-insulator substrate containing a top semiconductor layer (not shown), the buried insulator layer 10, and the handle substrate 6 is provided. The top semiconductor layer is lithographically patterned and etched to form isolated islands from the remaining top semiconductor layer separated by trenches with exposed surfaces of the buried insulator layer 10 underneath. Each of the isolated islands constitutes an active region, while the trenches are filled with a dielectric material such as an oxide and planarized to form the shallow trench isolation. Pad layers may be employed as necessary during these processing steps.

Optionally but preferably, a photoresist (not shown) is applied over the planarized surfaces of the semiconductor substrate containing an active region and the shallow trench isolation 30. The photoresist is lithographically patterned employing an implant mask (not shown) that exposes the implant area 21 while blocking the rest of the area of the semiconductor substrate. The implant area 21 contains the area of the body contact region 22 and may contain an additional area over the shallow trench isolation 30. The body to body contact region boundary 25 substantially coincides with an edge of the implant area 21. However, thermal diffusion during subsequent anneal steps and/or angled implantation of dopants into the body contact area 22 may cause some displacement of the body to body contact region boundary 25 relative to the edge of the implant area 21. Dopants of the first conductivity type are implanted into the body contact region 22. The photoresist is subsequently removed. It is noted that the masking of the area outside the implant area and implantation of the ions into the body contact region 22 may be performed at a different step of the processing sequence.

A gate dielectric layer and a gate conductor layer are formed and lithographically patterned to form the gate stack comprising the gate dielectric 40 and the gate conductor 50. The dielectric gate spacer 60 is formed by deposition of a dielectric material and a reactive ion etch.

It should be noted that the formation of the dielectric gate spacer 60 requires a structure that protrudes above the surface of the semiconductor substrate, i.e., the top surfaces of the active region (20, 22, 24) and/or the shallow trench isolation. For example, the protruding structure may be a patterned gate stack that comprises the gate dielectric 40 and the gate conductor 50. The dielectric gate spacer 60, therefore, is formed around the protruding structure. Unless the protruding structure has a hole having a dimension less than twice the thickness of the gate dielectric layer so that a mandrel may be formed, the dielectric gate spacer 60 is in general formed as a structure having at least one topological handle, or loosely speaking, a hole in the structure, wherein the location of the hole corresponds to the protruding structure. Thus, the dielectric gate spacer 60 is not topologically homeomorphic to a closed 3-dimensional unit ball, D³. Also, even when a mandrel is formed inside a hole-shaped protruding structure, a gate spacer that is not topologically homeomorphic to a closed 3-dimensional unit ball, D³, is formed on the outer sidewalls of the protruding structure.

A background in topology is briefly described herein. In mathematics, a ball is the inside of a sphere; both concepts apply not only in the three-dimensional space but also for lower and higher dimensions, and for metric spaces in general. In n-dimensional Euclidean space with the ordinary (Euclidean) metric, if the space is the line, the ball is an interval, and if the space is the plane, the ball is the disc inside a circle. A unit ball is a ball of radius 1. An open ball excludes the points of radius 1, and a closed ball includes the points of radius 1. A closed unit ball is denoted by Dⁿ; its outside is the (n−1)-sphere Sⁿ⁻¹, e.g., the 3-sphere S³ is the outside of D⁴ in 4D. The difference set between an n-dimensional unit closed ball and an n-dimensional unit open ball is an n−1 dimensional unit sphere.

In view of the above, when at least one dielectric spacer 60 is formed by the reactive ion etch, the at least one dielectric spacer 60 inherently has at least one topological handle, and consequently, cannot be topologically homeomorphic to a closed 3-dimensional unit ball, D³. The dielectric spacer 60 may be homeomorphic to a torus, which has one topological handle, as shown in FIGS. 2A and 2B. In case at least another protruding structure is present within twice the thickness of the dielectric gate spacer 60 of the sidewalls of the gate stack, the dielectric spacer 60 may have multiple handles, that is, may be continuously stretched and bended to a shape formed by adjoining multiple tori.

Conventional processing steps may be employed to form source and drain regions 24 by masked ion implantation and optionally form other semiconductor devices. Alternately, formation of the source and drain regions may be postponed until after the exposure of a body contact region to be described below.

Referring to FIGS. 3A and 31B, a gate cut mask is employed to cut off a portion of the gate stack (40, 50) and to expose a portion of the body contact region 22, a gate dielectric sidewall 41, and a gate conductor sidewall 51. Specifically, another photoresist (not shown) is applied over the semiconductor substrate. A block mask having an edge over the area of the body contact region 22 is employed to lithographically pattern the another photoresist such that the portion of the gate stack (40, 50) over the body 20 is covered by the another photoresist, while another portion of the gate stack (40, 50) over the body contact region 22 is exposed. A reactive ion etch is employed to remove the another portion of the gate stack (40, 50) above the body contact region.

The edge of the patterned photoresist may be located above the dielectric gate spacer 60 such that the edge intersects the gate dielectric spacer twice. The edge of the patterned photoresist may, or may not, be a straight line over the body contact area 22 and over the dielectric gate spacer 60. In this case, the remaining portion of the dielectric gate spacer 60 may be topologically homeomorphic to a closed 3-dimensional unit ball, D³. Further, the remaining portion of the gate conductor 50 may also be topologically homeomorphic to a closed 3-dimensional unit ball, D³.

A metal layer (not shown) comprising a metal or a metal alloy is formed directly on the surfaces of the first exemplary semiconductor structure including the top surface of the gate conductor 50 located on the exposed portion of the body contact region 22, the gate dielectric sidewall 41, the gate conductor sidewall 51, and top surfaces of the source and drain regions 24. The metal layer comprises a metal or a metal alloy capable of forming a first metal semiconductor alloy with the semiconductor material of the gate conductor 50. The metal or the metal alloy is also capable of forming a second metal semiconductor alloy with the semiconductor material of the body contact region 22, which comprises substantially the same material as the source and drain regions 24 except for differences in doping. In case the gate conductor comprises silicon, the first metal semiconductor alloy is a first silicide. In case the active region (20, 22, 24) comprises silicon, the second metal semiconductor alloy is a second silicide. Germanides or other metal compound semiconductor alloy may be formed depending on the composition of the active area (20, 22, 24) and the composition of the gate conductor 50.

The preferred thickness of the metal layer ranges from about 10 nm to about 50 nm, more preferably from about 5 nm to about 10 nm. The metal layer can be readily deposited by any suitable deposition technique, including, but not limited to: atomic layer deposition (ALD), chemical vapor deposition (CVD), and physical vapor deposition (PVD). Optionally, a metal nitride capping layer (not shown) may be deposited over the metal layer. The metal nitride capping layer may contain a refractory metal nitride such as TaN, TiN, OsN and may have a thickness ranging from about 5 nm to about 50 nm, preferably from about 10 nm to about 20 nm.

The first exemplary structure is thereafter annealed at a pre-determined elevated temperature at which the metal layer reacts with the underlying semiconductor material to form various metal semiconductor alloy regions. A portion of the body contact region 22 and portions of the source and drain regions 24 are consumed near the exposed top surfaces to form substrate metal semiconductor alloy regions 72 comprising a substrate metal semiconductor alloy. A portion of the gate conductor 50 is consumed near the exposed top surface and the gate conductor sidewall 51 to form a gate metal semiconductor alloy region 70 comprising a gate metal semiconductor alloy. The substrate metal semiconductor alloy and the gate metal semiconductor alloy are derived from the same metal or from the same metal alloy. As a consequence of the consumption of some of the semiconductor material from the gate conductor 50, the gate conductor sidewall may laterally move by the thickness of the consumed portion of the gate conductor 50. Ignoring the small shift, the gate dielectric sidewall 41 and the gate conductor sidewall 51 are substantially coincident when viewed from above.

Since the exposed top surface of the body contact region 22 and the gate conductor sidewall 51 is separated by a distance that is equal to the thickness of the gate dielectric 40, which is typically from about from about 1 nm to about 3 nm, while the thickness of the substrate metal semiconductor alloy regions 72 and the thickness of the gate metal semiconductor alloy regions 70 are from about 10 nm to about 50 nm, and typically from about 20 nm to about 30 nm, the substrate metal semiconductor alloy regions 72 and the gate metal semiconductor alloy regions 70 are adjoined to each other during the silicidation process.

Thus, a low resistance conduction path, or a gate-to-body bridge, is provided between the gate conductor 50 and the body 20 of an SOI MOSFET by the gate metal semiconductor alloy regions 70, the substrate metal semiconductor alloy region 72 on the body contact region 22, and the body contact region 22. Specifically, the gate conductor 50 abuts the gate metal semiconductor alloy regions 70, which abuts the substrate metal semiconductor alloy regions 72 abutting the body contact region 22, which abuts the body 20. The gate conductor 50 and the gate semiconductor alloy region are topologically homeomorphic to a closed 3-dimensional unit ball, D³, respectively.

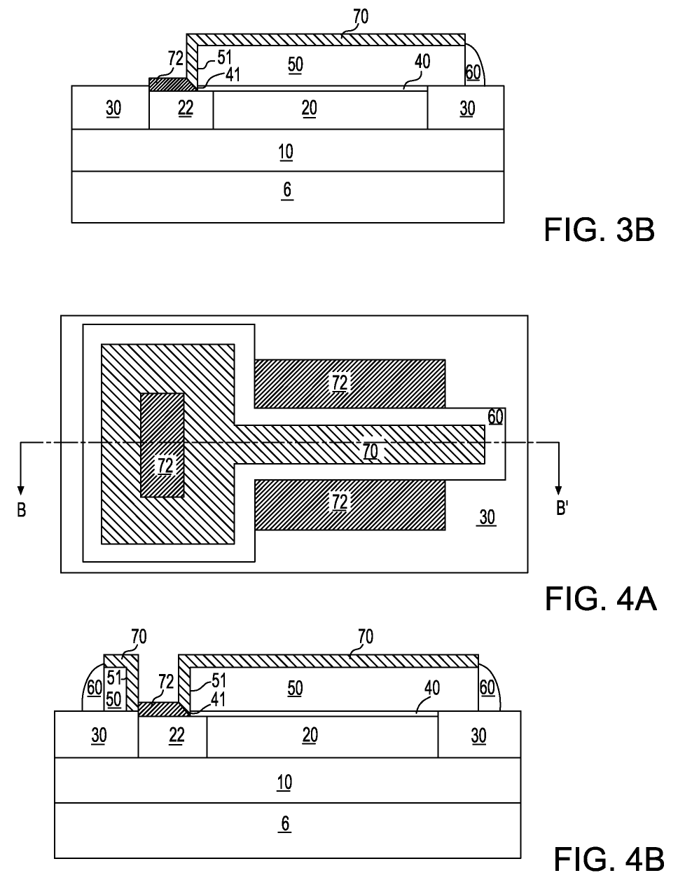

Referring to FIGS. 4A and 4B, a second exemplary structure according to a second embodiment of the present invention is shown. The first exemplary structure shown in FIGS. 2A and 2B are employed to form the second exemplary structure. A gate cut mask is employed to cut off a portion of the gate stack (40, 50) and to expose a portion of the body contact region 22, a gate dielectric sidewall 41, and a gate conductor sidewall 51 as in the first embodiment of the present invention. However, the edges of the patterned photoresist are not located above the dielectric gate spacer 60, and are located above the body contact area 22 so that a cavity is formed within the gate stack (40, 50) above a portion of the body contact area, A top surface of the body contact area 22 is exposed under the cavity. In this case, the remaining portion of the dielectric gate spacer 60 is not topologically homeomorphic to a closed 3-dimensional unit ball, D³, and may be topologically homeomorphic to a torus instead. Further, the remaining portion of the gate conductor 50 may also be topologically homeomorphic to a torus.

A metal layer (not shown) comprising a metal or a metal alloy is formed directly on the surfaces of the second exemplary semiconductor structure including the top surface of the gate conductor 50 located on the exposed portion of the body contact region 22, gate dielectric sidewalls 41, gate conductor sidewalls 51, and top surfaces of the source and drain regions 24.

Employing the same methods as in the first embodiment of the present invention, a low resistance conduction path, or a gate-to-body bridge, is provided between the gate conductor 50 and the body 20 of an SOI MOSFET by the gate metal semiconductor alloy regions 70, the substrate metal semiconductor alloy region 72 on the body contact region 22, and the body contact region 22. In the second exemplary structure, the gate conductor 50 and the gate semiconductor alloy region, and the dielectric gate spacer 60 are not topologically homeomorphic to a closed 3-dimensional unit ball, D³, but may be topologically homeomorphic to a torus instead. However, the set of metal semiconductor alloys that are contiguous with the gate metal semiconductor alloy 70, i.e., the adjoined structure of the gate metal semiconductor alloy 70 and the substrate metal semiconductor alloy 72 that is located above the body contact region 22, is topologically homeomorphic to a closed 3-dimensional unit ball, D³ since no hole is present in the contiguous structure.

While the invention has been described in terms of specific embodiments, it is evident in view of the foregoing description that numerous alternatives, modifications and variations will be apparent to those skilled in the art. Particularly, variations of geometry of the gate cut mask to produce various topological configurations and/or multiple cavities in the gate conductor are explicitly contemplated herein. Accordingly, the invention is intended to encompass all such alternatives, modifications and variations which fall within the scope and spirit of the invention and the following claims.

What is claimed is:

1. A semiconductor-on-insulator (SOI) metal oxide semiconductor field effect transistor (MOSFET) comprising:
an active region surrounded by shallow trench isolation and containing a body, source and drain regions, and a body contact region, wherein said body contact region abuts said body;
a buried insulator layer abutting said active region and said shallow trench isolation;
a handle substrate abutting said buried insulator layer;
a gate stack abutting said body and containing a gate dielectric and a gate conductor;
a substrate metal semiconductor alloy region abutting said body contact region; and
a gate metal semiconductor alloy region abutting a gate conductor sidewall and abutting said substrate metal semiconductor alloy region.

2. The SOI MOSFET of claim 1, wherein said body and said body contact region are doped with dopants of a first conductivity type and said source and drain region is doped with dopants of a second conductivity type, wherein said first conductivity type is the opposite of said second conductivity type.

3. The SOI MOSFET of claim 2, wherein said body contact region is heavily doped and has an atomic doping concentration from about 1.0×10²⁰/cm³ to about 3.0×10²¹/cm³.

4. The SOI MOSFET of claim 2, wherein said gate conductor comprises a semiconductor material doped with dopants of the second conductivity type.

5. The SOI MOSFET of claim 1, further comprising a gate dielectric sidewall adjoining said gate conductor sidewall and said body contact region.

6. The SOI MOSFET of claim 1, further comprising a dielectric gate spacer abutting at least another gate conductor sidewall and not abutting said gate conductor sidewall, wherein said dielectric gate spacer is topologically homeomorphic to a closed 3-dimensional unit ball, D³ and is not topologically homeomorphic to a torus.

7. The SOI MOSFET of claim 1, wherein said gate conductor is topologically homeomorphic to a torus, said gate metal semiconductor alloy region is topologically homeomorphic to a torus, and the adjoined structure of said gate metal semiconductor alloy region and said gate metal semiconductor alloy is topologically homeomorphic to a closed 3-dimensional unit ball, D³.

8. The SOI MOSFET of claim 1, wherein a substrate metal semiconductor alloy in said substrate metal semiconductor alloy region and a gate metal semiconductor alloy in said gate metal semiconductor alloy region are derived from the same metal or metal alloy.

9. The SOI MOSFET of claim 7, wherein said substrate metal semiconductor alloy region and said gate metal semiconductor alloy are the same metal silicide.
